(19) United States
(12) Patent Application Publication
(10) Pub. No.: US 2025/0035866 A1
(43) Pub. Date: Jan. 30, 2025

(54) LIGHT SOURCE DEVICE AND OPTICAL COUPLING STRUCTURE AND OPTOELECTRONIC SYSTEM USE THEREOF

(71) Applicant: AIP Inc., New Taipei City (TW)

(72) Inventor: Chia Lee, New Taipei City (TW)

(73) Assignee: AIP Inc., New Taipei City (TW)

(21) Appl. No.: 18/780,529

(22) Filed: Jul. 23, 2024

Related U.S. Application Data
(63) Continuation-in-part of application No. 18/510,668, filed on Nov. 16, 2023.
Application No. 18/510,668 is a continuation of application No. 63/528,933, filed on Jul. 26, 2023.
(60) Provisional application No. 63/624,809, filed on Jan. 25, 2024.

(51) Int. Cl. G02B 6/42; H01S 5/042; H01S 5/42

(52) U.S. Cl. CPC G02B 6/4249; G02B 6/421; H01S 5/0425; H01S 5/423

(57) ABSTRACT

An optical coupling structure, adapted for an optoelectronic device, includes a light source device including a fixed board, a bar substrate positioned on the fixed board, and a light unit positioned on the bar substrate. The light unit includes a functional portion and a light-emitting portion that are divided into a plurality of light emitters, and the bar substrate is configured to cross a bottom of each of the light emitters. A waveguide device is disposed adjacent to a mating surface included in the fixed board and the light emitters of the light source and enables light signal transmission from the light emitters. An optical fiber assembly connected to the waveguide device.

### CROSS REFERENCE TO RELATED APPLICATIONS

This application claims the benefit of U.S. provisional patent application Ser. No. 63/624,809, filed Jan. 25, 2024, the entirety of which is incorporated by reference herein.

This application is a continuation-in-part of U.S. patent application Ser. No. 18/510,668 filed Nov. 16, 2023, which claims the priority of U.S. provisional patent application Ser. No. 63/528,933, filed Jul. 26, 2023, the entireties of which are incorporated by reference herein.

### BACKGROUND OF INVENTION

### 1. Field of Invention

The present invention relates to a technical field of optoelectronic integrated circuits (OEIC), and particularly to a light source device adapted for use with the optoelectronic device, an optical coupling structure, and an optoelectronic system.

### 2. Related Art

Optoelectronic integrated circuits (OEICs), using photons instead of electrons for calculation and data transmission in integrated circuits, bring great benefits to the development of industries requiring high-performance data exchange, long-distance interconnection, 5G facilities, and computing equipment. OEICs are configured with photonic integrated circuits (PICs) and electronic integrated circuits (EICs) and are generally co-packaged as co-packaged optics (CPO).

Generally, the production of optical communication modules requires light-emitting components to be bonded to substrates first, and then after optical coupling alignment processes, each component is combined and bonded to complete the optical communication module. However, during the optical coupling process, active components such as laser diodes or light-emitting diodes must be driven and actively aligned with optical fibers. Once optical communication modules are configured with multiple light-emitting elements, the above-mentioned active alignment step of optical coupling must be performed on each light-emitting element. Such a method is quite time-consuming and tends to cause inconsistent optical path positions between multiple light-emitting elements, thus adversely affecting the transmission quality of optical signals.

### SUMMARY OF INVENTION

An object of the present application is to provide an optical coupling structure, which is adapted for an optoelectronic device and configured with a plurality of light emitters that can be optically aligned at one time with a waveguide device and can ensure precise and efficient optical alignment.

Another object of present application is to provide a light source device, which serves as an external high power light source for the optoelectronic device.

To achieve the above-mentioned objects, one aspect of the present application is to provide an optical coupling structure adapted for an optoelectronic device, the optical coupling structure including a light source device, a waveguide device, and an optical fiber assembly. The light source device includes a fixed board, a bar substrate positioned on the fixed board, and a light unit positioned on the bar substrate. The light unit includes a functional portion and a light-emitting portion that are divided into a plurality of light emitters, and the bar substrate is configured to cross a bottom of each of the light emitters. The waveguide device is disposed adjacent to a mating surface included in the fixed board and the light emitters of the light source and enabling light signal transmission from the light emitters. The optical fiber assembly is connected to the waveguide device.

Optionally, the light emitters are spaced apart from each other and arranged in alignment with each other in an array.

Optionally, the bar substrate includes an electrical circuit coupling with each of the light emitters and configured to provide a driving voltage to the light emitters.

Optionally, the light emitters are laser emitters and each of the light emitters is concurrently optically coupled with the waveguide device through a one-time active alignment process.

Optionally, the waveguide device includes a plurality of optical waveguide paths spaced apart from each other at a same pitch as a pitch between adjacent ones of the light emitters.

Optionally, the bar substrate is positioned close to the mating surface of the fixed board, and the light emitters emit light beams in a straightforward direction toward the waveguide paths, respectively.

Optionally, the waveguide device includes a guide surface located at a front end of the waveguide device, the waveguide paths extend to the guide surface, and the guide surface is configured to face and close to the mating surface of the fixed board such that the light emitters are in alignment with the waveguide paths with a hollow space kept between the light emitters and the waveguide paths, respectively.

Optionally, the optical fiber assembly includes a base and a plurality of optical fibers, part of the optical fibers is positioned at the base, and one end of each of the optical fibers is terminated at an edge of the base close to the waveguide device.

Optionally, a casing board is provided to support the optoelectronic device, and the optical coupling structure is mounted to the casing board, and the casing board, the optoelectronic device, and the optical coupling structure collectively form an optoelectronic system.

Another aspect of the present application is to provide a light source device, adapted for use with an optoelectronic device, and including a fixed board, a bar substrate, and a light unit. The bar substrate positioned on the fixed board. The light unit is positioned on the bar substrate and includes a functional portion, a light-emitting portion, and a plurality of electrodes electrically connecting the light unit with the bar substrate. The functional portion and the light-emitting portion are divided into a plurality of light emitters, and the electrodes are arranged on the light emitters, respectively.

Optionally, the functional portion includes an N-type semiconductor structure and a P-type semiconductor structure, and the light-emitting portion is disposed between the N-type semiconductor structure and the P-type semiconductor structure.

Another aspect of the present application is to provide an optoelectronic system, including: an optical coupling structure and an optoelectronic device. The optical coupling structure includes a light source device, a waveguide device, and an optical fiber assembly. The light source device includes: a fixed board; a bar substrate positioned on the fixed board; and a light unit positioned on the bar substrate and including a functional portion, a light-emitting portion. The functional portion and the light-emitting portion are divided into a plurality of light emitters. The waveguide device is disposed adjacent to the fixed board and the light emitters of the light source and enabling light signal transmission from the light emitters. The optical fiber assembly includes a plurality of optical fibers and is connected to the waveguide device. The optoelectronic device includes a main circuit board and a plurality of detachable optical transceiver modules arranged on peripheral portions of the main circuit board. Each of the detachable optical transceiver module includes a first connector and a second connector. The first connector is disposed on the main circuit board and includes a base and a waveguide device disposed in the base. The second connector is disposed at one end of each optical fiber. The second connector is detachably connected to the first connector.

Optionally, the light emitters are laser emitters and each of the light emitters is concurrently optically coupled with the waveguide device through a one-time active alignment process.

Optionally, the optoelectronic system further includes a casing board provided to support the optoelectronic device and the optical coupling structure.

Optionally, the optical fiber assembly includes a base. Part of the optical fibers is positioned at the base. Another end of each of the optical fibers is terminated at an edge of the base close to the waveguide device.

In the embodiments of the present application, the light source device of the optical coupling structure serves as an external light source (ELS) for the optoelectronic device and replaces conventional light source elements that are separately formed into a single piece, thus achieving optical coupling with multiple optical paths at one time and preventing the problem of high manufacturing costs and poor assembly efficiency resulting from the fact that conventional multiple light source elements each need to go through complicated and time-consuming optical alignment and coupling processes with lens components between the light source elements and optical fibers.

### BRIEF DESCRIPTION OF DRAWINGS

To describe the technical solutions in the embodiments of the present application, the following briefly introduces the drawings for describing the embodiments. The drawings in the following description show merely some embodiments of the present application, and a person skilled in the art may still derive other drawings from these drawings without creative efforts.

FIG. 1 is a schematic assembly view of an optical coupling structure in accordance with an embodiment of the present application.

FIG. 1A is a schematic partially enlarged view of the optical coupling structure of FIG. 1.

FIG. 2 is a schematic exploded view of the optical coupling structure of FIG. 1.

FIG. 2A is a schematic partially enlarged view of the optical coupling structure of FIG. 2.

FIG. 3 is a schematic top plan view of FIG. 1.

FIG. 4 is a schematic cross-sectional view taken along line A-A of FIG. 3 in accordance with an embodiment of the present application.

FIG. 5A is a schematic cross-sectional view of an optical coupling structure in accordance with an embodiment of the present application.

FIG. 5B is a schematic cross-sectional view of an optical coupling structure in accordance with an embodiment of the present application.

FIG. 5C is a schematic cross-sectional view of an optical coupling structure in accordance with an embodiment of the present application.

FIG. 6 is a schematic perspective view showing an optoelectronic system in accordance with an embodiment of the present application.

FIG. 7A is a schematic perspective assembly view of

FIG. 7B is a schematic exploded view of FIG. 7A.

### DESCRIPTION OF PREFERRED EMBODIMENTS

The following disclosure provides many different embodiments, or examples, for implementing different features of the provided subject matter. Specific examples of components and arrangements are described below to simplify the present application. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present application may repeat reference numerals and/or letters in the various examples. This repetition is for the purpose of simplicity and clarity and does not in itself dictate a relationship between the various embodiments and/or configurations discussed.

The following embodiments are referring to the appendix drawings for exemplifying specific implementable embodiments of the present application. Directional terms described by the present application, such as upper, lower, front, back, left, right, inner, outer, side, etc., are only directions by referring to the drawings, and thus the used directional terms are used to describe and understand the present application, but the present application is not limited thereto.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present application. In addition, the present application may repeat reference numerals and/or letters in the various examples. This repetition is for the purpose of simplicity and clarity and does not in itself dictate a relationship between the various embodiments and/or configurations discussed.

The present application provides an optical coupling structure for an optoelectronic device. In some embodiments, the optoelectronic device may be a co-packaged optics (CPO) device that integrates at least an electronic integrated circuit (EIC) and at least a photonic integrated circuit (PIC) in a single package for electro-optic conversion or optic-electro conversion. Preferably, the optical coupling structure provided by the embodiments of the present application may server as a high-power external light source for the optoelectronic device.

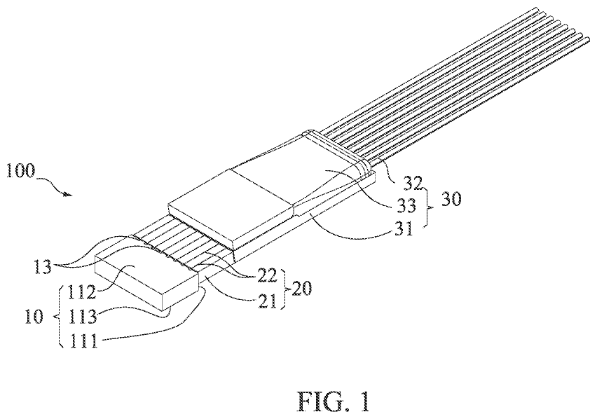

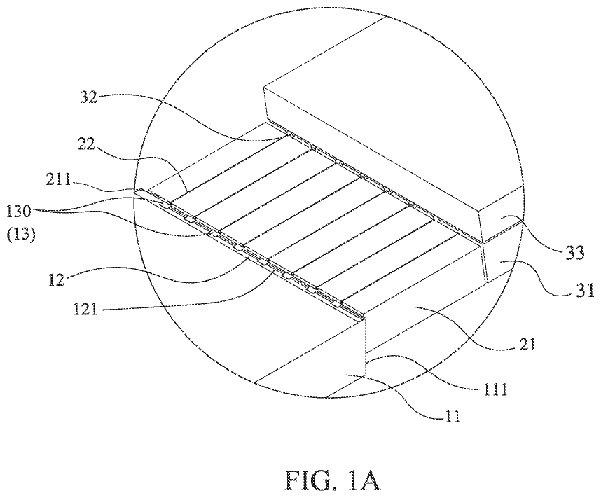

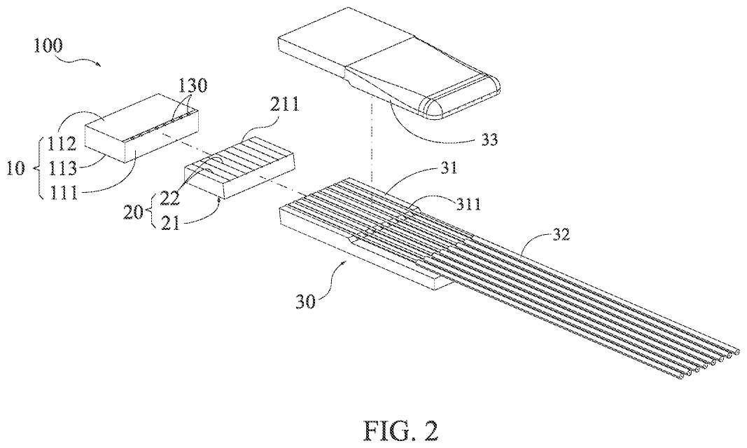

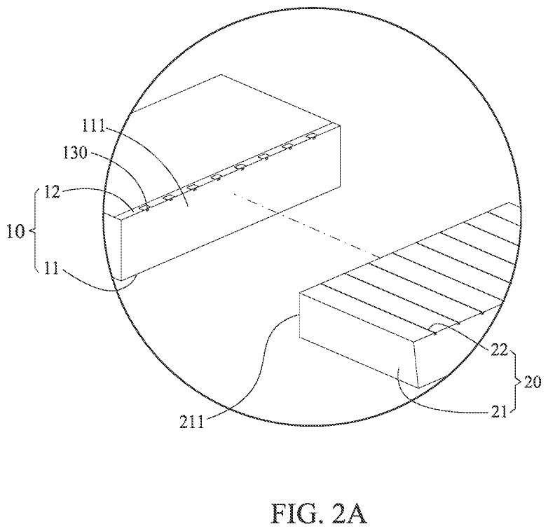

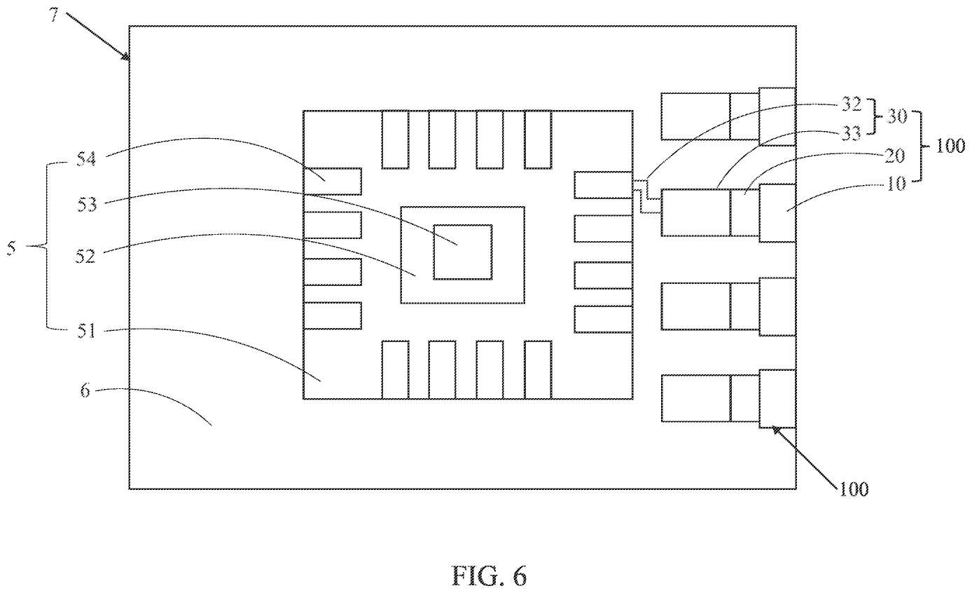

Referring to FIGS. 1 to 2, FIG. 1 is a schematic assembly view of an optical coupling structure 100 according to an embodiment of the present application, FIG. 1A is a schematic partially enlarged view of the optical coupling structure of FIG. 1, and FIG. 2 is a schematic exploded view of the optical coupling structure 100 of FIG. 1. As shown in FIGS. 1 and 2, the optical coupling structure 100 includes a light source device 10, a waveguide device 20, and an optical fiber assembly 30. Specifically, the waveguide device 20 is bonded to one end of the optical fiber assembly 30, and the light source device 10 is attached to one end of the waveguide device 20 away from the optical fiber assembly 30. In this embodiment, the light source device 10 is configured to provide light beams with desired power for an optoelectronic device 5 (as shown in FIG. 6 described below) by transmitting the light through the waveguide device 20 to the optical fiber assembly 30 for reception by the optoelectronic device 5.

Referring to FIG. 2A in combination with FIGS. 1 to 2, FIG. 2A is a schematic partially enlarged view of the optical coupling structure 100 of FIG. 2. As shown in FIGS. 1 and 1A, the light source device 10 includes a fixed board 11, a bar substrate 12, and a light unit 13. The fixed board 11 is a printed circuit board being rectangular in shape and includes a top surface 112, a bottom surface 113, and a mating surface 111 connected between the top surface 112 and the bottom surface 113. The bar substrate 12 is positioned on the fixed board 11, and the light unit 13 is positioned on the bar substrate 12. In some embodiments, as shown in FIGS. 1A and 2A, the bar substrate 12 is positioned close to the mating surface 111 of the fixed board 11 and includes a driving circuit 121 electrically coupled with the light unit 13.

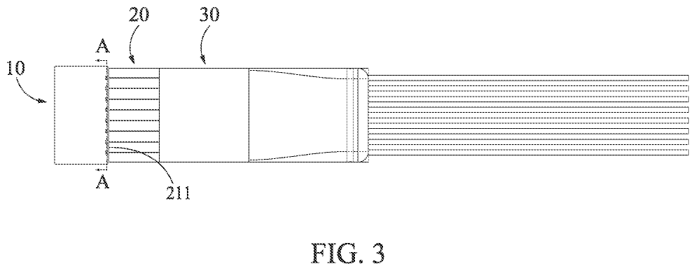

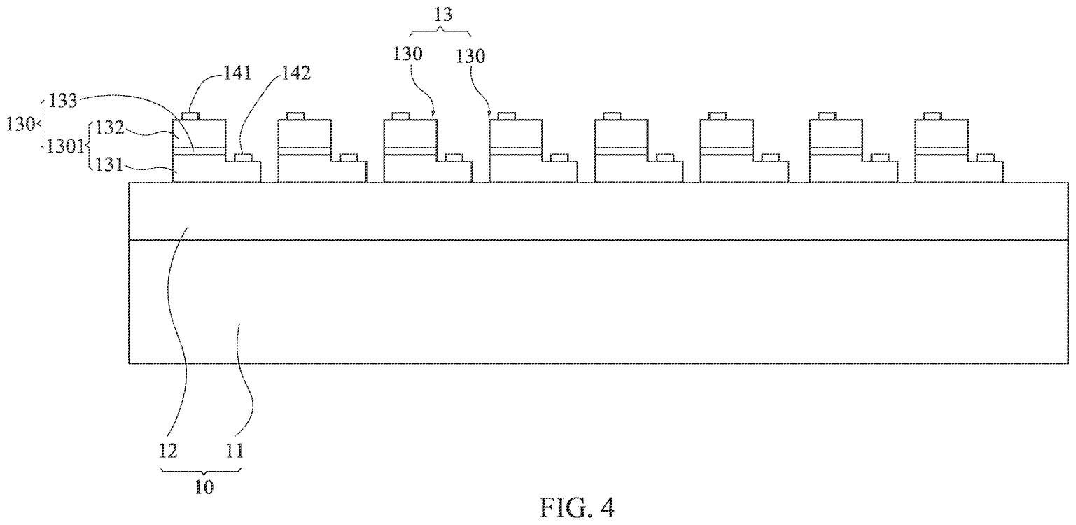

Referring to FIGS. 3 and 4, FIG. 3 is a schematic top plan view of FIG. 1, and FIG. 4 is a schematic cross-sectional view taken along line A-A of FIG. 3. As shown in FIG. 4, the light unit 13 includes a functional portion 1301 and a light-emitting portion 133. In this embodiment, the light unit 13 is fabricated via LED forming process such as epitaxy on the bar substrate 12 at the same time. Specifically, the light unit 13 and the bar substrate 12 are fabricated by thin film growth processes, lithography, doping processes, and etching processes. The light unit 13, after undergoing the film growth processes, etc., is disponed on the bar substrate 12 and is further divided into a plurality of light emitters 130 through the etching processes such that the plurality of light emitters 130 are spaced apart from each other and arranged in alignment with each other. There is no need to perform LED die sawing (as known as dicing) and binning processes. As shown in FIGS. 2A and 4, the bar substrate 12 is configured to cross a bottom of each of the light emitters 130. The light emitters 130 are used to generate base band optical signals, which usually refers to converting electrical energy into light energy.

Still referring to FIG. 4, the functional portion 1301 of the light emitter 130 includes an N-type semiconductor structure 131 and a P-type semiconductor structure 132. The light-emitting portion 133, made of a semiconductor material, such as gallium arsenide (GaAs), is disposed between the N-type semiconductor structure 131 and the P-type semiconductor structure 132. Each of the light emitters 130 further includes a plurality of electrodes 14 each including an anode 141 and a cathode 142 that are formed on the N-type semiconductor structure 131 and the P-type semiconductor structure 132, respectively. In some embodiments, the light emitters 130 are laser emitters, for example, such as gallium arsenide (GaAs) laser diodes, gallium nitride (GaN) laser diodes, or indium gallium arsenide phosphide (InGaAsP) laser diodes, but are not limited thereto.

In some embodiments, the light emitters 130 need to be epitaxially grown first, that is, N-type semiconductors 131, P-type semiconductors 132, and light-emitting portion 133 are grown on the bar substrate 12. Taking gallium nitride laser diodes as an example. GaN laser diodes are grown on sapphire substrates. A growth method can be metal organic chemical-vapor deposition (MOCVD). Particularly, the plurality of the light emitters 130 are fabricated at the same time on the bar substrate 12. In detail, as shown in FIG. 4, after all layers of the light emitters 130 are formed in turn on the bar substrate 12 as an entire surface to include all the light emitters 130, an etching process is performed to divide the layers except the sapphire substrate so formed into a plurality of units of the light emitters 130. Then, use a dry etching method to dig out part of a surface of the P-type semiconductor 132 of each light emitter 130 to expose the N-type semiconductor structure 131 underneath, and then provide electrodes 14 on the P-type and N-type semiconductors 132 and 131 (as well as the driving circuit 121 on the bar substrate 12 as shown in FIG. 1A) so that current can pass through and emit light. It should be noted that the method of fabricating the light emitters 130 are not limited thereto.

In some embodiments, the light emitters 130 of the present application may be edge emitting laser diodes, surface emitting laser diodes, or vertical cavity surface emitting laser (VCSEL) diodes. Specifically, the edge emitting laser diodes operate in a manner that an epitaxial plane is in the horizontal direction, and the laser light resonates back and forth in the horizontal direction (in the epitaxial plane) and is emitted from the side surface. The surface emitting laser diodes operate in a manner that an epitaxial plane and a metal reflective film are both in the vertical direction, and the laser light resonates back and forth in the direction perpendicular to the epitaxial plane and is emitted from the epitaxial surface. The VCSEL diodes operate in a manner that the laser light is emitted from the direction perpendicular to the surface of the semiconductor substrate.

Referring to FIG. 1A, the bar substrate 12 includes a driving circuit 121 coupling with the electrodes 14 of each of the light emitters 130 and configured to provide a driving voltage or driving current to the light emitters 130 as well as providing the power as required to the light emitters 130. In some embodiments, the bar substrate 12 has the characteristics of high temperature resistance, corrosion resistance, high hardness, and high melting point. Preferably, the bar substrate 12 is a sapphire substrate or gallium arsenide (GaAs) substrate depending on types of the light emitters 130.

As shown in FIG. 1A, the driving circuit 121 is configured along the light emitters 130. In some embodiments, the driving circuit 121 may output the driving voltage to a certain number of the light emitters 130 to emit laser light with a first predetermined power. In other embodiments, the driving circuit 121 may output another driving voltage to the remaining light emitters 130 to emit laser beams with a second predetermined power which is greater than the first predetermined power. Preferably, all the light emitters 130, under the control of the driving voltage, output laser beams with the first predetermined power or the second predetermined power depending on applications. Preferably, the light source device 10 is configured to generate the high-power narrowband light with an intensity of over 500 microwatts (mW) depending on the application.

As shown in FIGS. 1 and 2, the waveguide device 20 is made of a material containing, for example, silica, silicon carbide (SiC), silicon nitride (SiN) and includes a waveguide substrate 21, a plurality of optical waveguide paths 22 formed on the waveguide substrate 21, and a guide surface 211 located at a front end of the waveguide substrate 21. In some embodiments, the optical waveguide paths 22 are groove-like shaped and are arranged in an array along a top surface of the waveguide substrate 21 to extend to the guide surface 211 for propagating light beams from the light source device 10 to the optical fiber assembly 30.

In some embodiments, the waveguide device 20 is of a planar light wave circuit (PLC), which may be configured in various ways, including, but not limited to, a straight line circuit, a splitter circuit, an arrayed waveguide grating wavelength multiplexer, and a cross connect-type circuit. Different types of waveguide circuits or devices can be utilized for the planar light wave circuit in the embodiments of the present application.

As shown in FIGS. 1A and 2, in some embodiments, the number of the waveguide paths 22 is equal to the number of the light emitters 130. The pattern on the mask used to etch the layers to form into a plurality of units of the light emitters 130 is design to match the optical waveguide paths 22 of the waveguide device 20. Specifically, the waveguide paths 22 are spaced apart from each other at a same pitch as a pitch between adjacent ones of the light emitters 130. When assembling the waveguide device 20 and the light source device 10, since the light emitters 130 are concurrently formed on the single bar substrate 12 as a whole and the light emitters 130 and the waveguide paths 22 are patterned through masks with matching pattern, one can quickly align all the light emitters 130 with the waveguide paths 22 at once by lighting all light emitters 130 and detecting light intensity from a plurality of optical fibers 32 included in the optical fiber assembly 30. In some embodiments, as shown in FIGS. 1 to 2A, the bar substrate 12 with the light emitters 130 is arranged close to the mating surface 111 and the top surface 112 of the fixed board 11. In other embodiments, the bar substrate 12 with the light emitters 130 may be disposed in a substantially middle portion between the top surface 112 and the bottom surface 113 or close to the bottom surface 113.

As shown in FIG. 1 and FIG. 2, the optical fiber assembly 30 includes a support seat 31, a cap 33 detachably attached to the support seat 31, and a plurality of optical fibers 32. Part of each of the optical fibers 32 is positioned at the support seat 31, and one end of each of the optical fibers 32 is terminated at an edge of the support seat 31 close to the waveguide device 20. The optical fibers 32 may be, for example, single-mode fibers, multi-mode fibers, or polarization-maintaining (PM) fibers, and are arranged in parallel with each other in a single row or multiple rows on the support seat 31. In this embodiment, the optical fibers 32 are single-mode fibers, and the support seat 31 includes a plurality of V-shaped grooves 311 to fix the optical fibers 32. The cap 33 is seized and shaped to protect the optical fibers 32 on the support seat 31. The support seat 31 is attached to the waveguide device 20 such that the optical fibers 32 are in alignment with the optical waveguide paths 22, respectively. Preferably, the support seat 31 is attached to the waveguide device 20 by applying glue or curing substance.

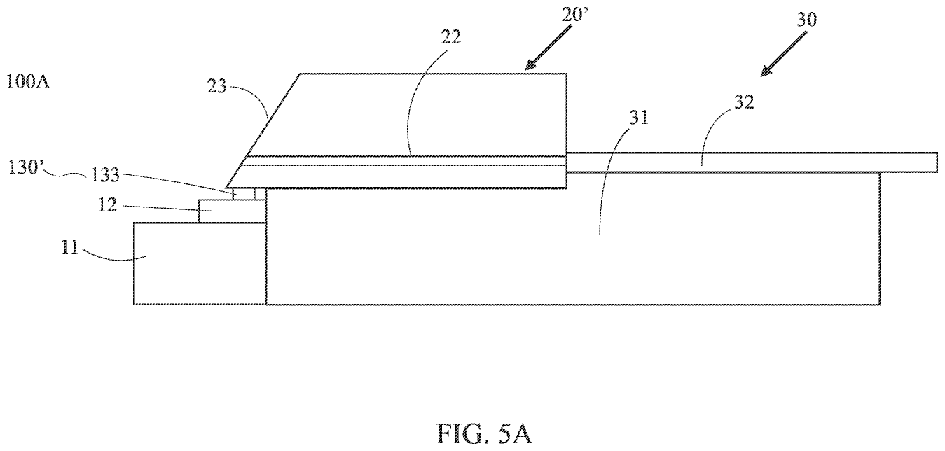

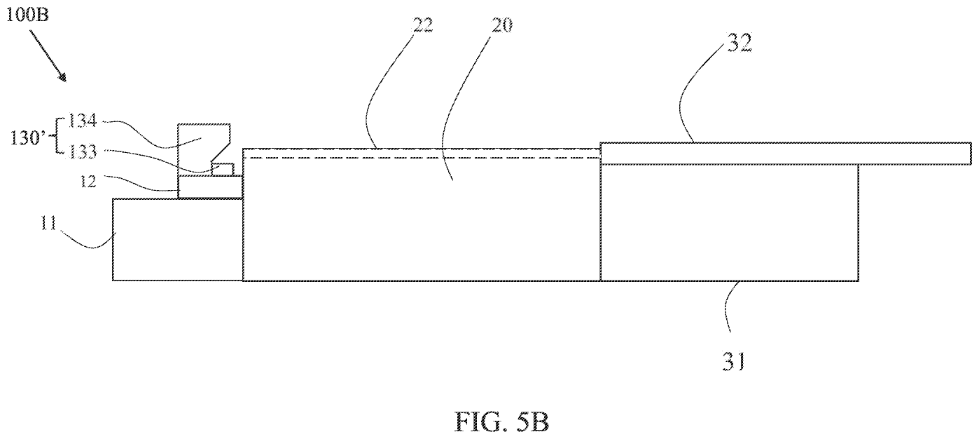

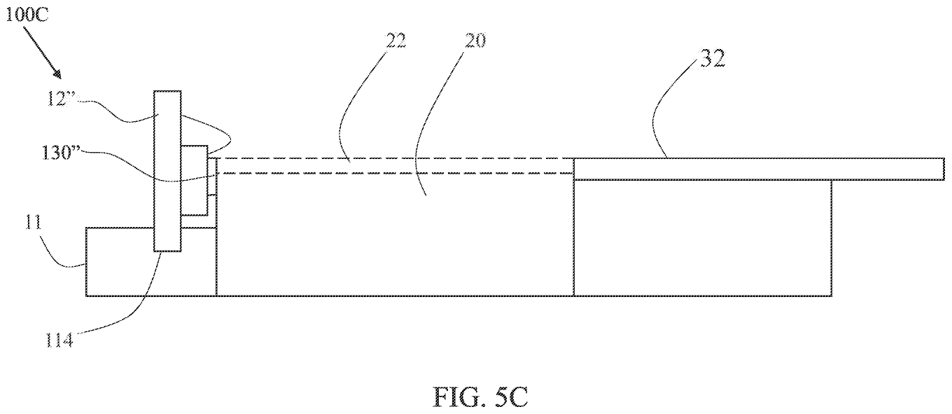

Referring to FIG. 5A, FIG. 5A is a schematic cross-sectional view of an optical coupling structure 100A in accordance with an embodiment of the present application. In this embodiment, the light emitters 130′ emit laser beams in an upward direction perpendicular to the bar substrate 12, and the waveguide device 20′ further includes a reflection wall 23 coated with a refection material. Specifically, the reflection wall 23 is located over the light-emitting portions 133 of the light emitter 130 such that the light, i.e., laser beam, is irradiated upward from each of the light-emitting portions 133 to strike the reflection wall 23 of the waveguide device 20 and reflected by the reflection wall 23 in a direction to the corresponding optical waveguide path 22. In some embodiments, as shown in FIG. 5A, the support seat 31 may extend forward to support the waveguide device 20′.

Referring to FIG. 5B, FIG. 5B is a schematic cross-sectional view of an optical coupling structure 100B in accordance with an embodiment of the present application. In this embodiment, the light emitters 130′ also emit laser beams in an upward direction perpendicular to the bar substrate 12. Specifically, each of the light emitters 130′ further includes a reflection bar 134 located over all of the light-emitting portion 133. The reflection bars 134 and the light emitters 130′ are concurrently fabricated on the bar substrate. In operation, the light is irradiated from the light-emitting portion 133 to the reflection bar 134 and reflected by the reflection bar 134 in a direction to the optical waveguide paths 22 of the waveguide device 20.

Referring to FIG. 5C, FIG. 5C is a schematic cross-sectional view of an optical coupling structure 100C in accordance with an embodiment of the present application. In this embodiment, the light emitters 130″ also emit laser beams in an upward direction perpendicular to the bar substrate 12″. Unlike the optical coupling structures described in the aforementioned embodiments, the bar substrate 12″ is rotated to be inserted into a slot portion 114 of the fixed board 11 such that the light emitter 130″ is 90-degree turned to be formed against the fixed board 11 and emits light travelling straight forward to the optical waveguide path 22 of the waveguide device 20.

The light emitters 130 provided in this application may be surface emitting lasers or edge emitting lasers, preferably the surface emitting lasers. The light emitters 130 described in the embodiments as described above are configured to generate laser beams having the shape of the light field maintained as a perfect circle or a desired shape according to the design of the optical fiber 32. Since the light emitters 130 can emit light beams, which are maintained in a desired shape and travel in a straightforward direction toward the waveguide paths 22, the energy loss of the light emitted by the litter emitters 130 is much less when connected to the optical fibers 32.

Referring to FIG. 6, FIG. 6 illustrating an optoelectronic system 7 in which the optical coupling structure 100 is adapted for the optoelectronic device 5 according to an embodiment of the present application. In some embodiments, the optoelectronic device 5 is configured on a casing board 6 and the optoelectronic device 5 includes a main circuit board 51, a load board 52 electrically mounted on the main circuit board 51, at least a processor 53 is arranged on the load board 52, and a plurality of detachable optical transceiver modules 54 are arranged on peripheral portions of the main circuit board 51. In some embodiments, the processor 53 may be an application specific integrated circuit (ASIC), and the load board 52 may be a multi-chip module (MCM) functioning as a substrate for multiple chips and perform various electrical and optical functions. In some embodiments, the optoelectronic device 5 may be embodied as a CPO switch, but is not limited thereto. As shown in FIG. 6, each side portion of the main circuit board 51 is provided with four optical transceiver modules 54. Alternatively, there may be eight optical transceiver modules 54 arranged on each side portion of the main circuit board 51. The number of the optical transceiver modules 54 is determined depending on actual applications.

In assembly, referring to FIGS. 1 to 2A, and 6, the optical coupling structure 100 is disposed on the casing board 6 and connected to the respective one of the optical transceiver modules 54 through the optical fiber assembly 30. Specifically, the waveguide device 20 is attached to the light source device 10 in such a way that the light emitters 130 are in optical alignment with the optical waveguide paths 22 of the waveguide device 20, respectively, and the mating surface 111 of the fixed board 11 is directly facing the guide surface 211 of the waveguide device 20. As shown in FIGS. 1A and 3, the guide surface 211 is configured to face the mating surface 111 such that the light emitters 130 are in alignment with the waveguide paths 22 with a hollow space kept between the light emitters 130 and the waveguide paths 22, respectively. Specifically, no optical lenses, zone plates, and the like, are disposed between the mating surface 111 and the guide surface 211 for propagating or directing light beams.

In some embodiments, the optical coupling structure 100 may be provided on an external casing (not shown) and is optoelectronically connected to the optical transceiver modules 54 through interconnectors (not shown) between the optical fibers 32 and the optical transceiver module 54. In other embodiments, the light source device 10 is fixedly disposed on the casing board 6, and the waveguide device 20 along with the optical fiber assembly 30 is detachably connected to the light source device 10 while ensuring precise and optical alignment between the waveguide device 20 and the light source device 10.

With the optical coupling structure 100 of the present application, there is no need to individually align each of the light emitters 130 with the corresponding waveguide path 22. Instead, only the first one and the last one of the light emitters 130 in the row are required to be actively aligned with the corresponding waveguide paths 22 (one-time active alignment process). In addition, each of the light emitters 130 emits a laser beam to pass straight through the corresponding waveguide path 22 to the corresponding optical fiber 32.

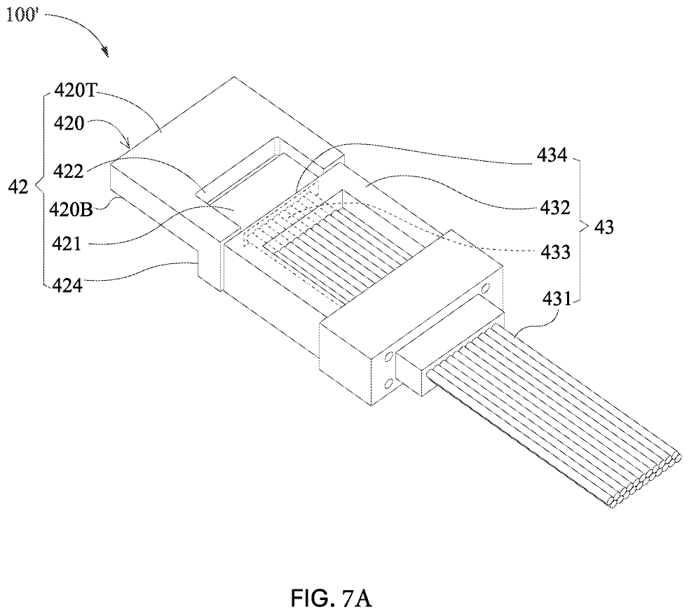

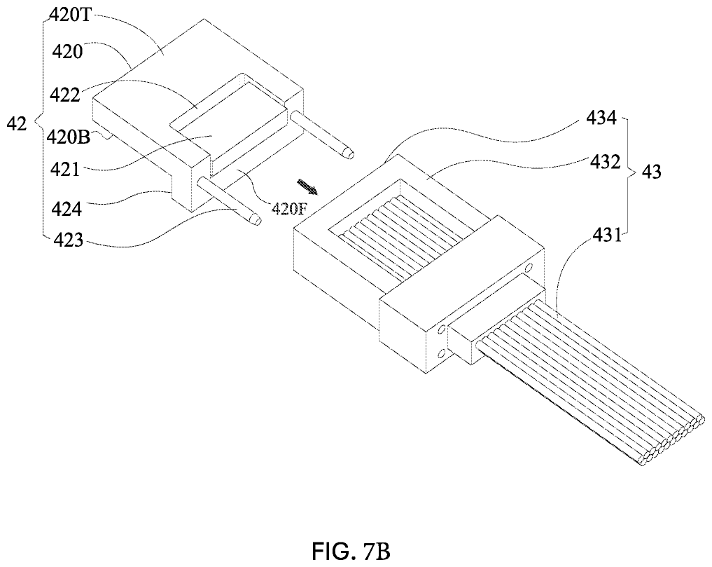

Referring to FIGS. 7A, and 7B, in some embodiments, the optical transceiver module 54 includes a detachable optical coupling structure 100′ including a first connector 42 and a second connector 43. The second connector 43 is detachably connected to the first connector 42 that can achieve the effect of easy replacement of the second connector 43. As shown in FIGS. 7A and 7B, the first connector 42 includes a base 420 and a waveguide component 421. The base 420 includes a lower surface 420B, an upper surface 420T, and a front end 420F connected between the lower surface 420B and the upper surface 420T. In some embodiments, a cutout portion 422 is formed in the base 420 and is recessed from the front end 420F, and the waveguide component 421 is disposed in the cutout portion 422. In detail, the cutout portion 422 is configured to pass through parts of the lower surface 420B, the upper surface 420T, and the front end 420F of the base 420.

In some embodiments, as shown in FIG. 7B, a plurality of positioning elements 423 are symmetrically arranged on the front end 420F of the base 420 with respect to a middle of the base 420, and are spaced apart from each other on opposite sides of the cutout portion 422 and the waveguide component 421. A retaining wall 424 is formed on the base 420 and bends and extends downward from the lower surface 420B such that the base 420 has an inverted L-shaped cross-sectional profile. In this embodiment, there are two positioning elements 423, which are pin-like in shape and extend in an outward direction from the front end 420F on the retaining wall 424, respectively. In some embodiments, the base 420 is made of material having the characteristic of high temperature resistance, such as ceramic or metal, which is, for example, zirconium dioxide (ZrO2). Alternatively, the base 420 may be made of non-metal material, such as organic binders (e.g., resin), polymer, or plastic.

Preferably, the waveguide component 421 is made of a material containing, for example, silica. Alternatively, the waveguide component 421 may be made of a material containing silicon-on-insulator (SOI), lithium niobate (LiNbO3), or polymers. In some embodiments, the waveguide component 421 may be formed using a material of such as fused silica, quartz, glass, borosilicate glass, etc. It should be noted that the waveguide component 421 includes a planar lightwave circuit (PLC). In some embodiments, the planar lightwave circuit may be configured in various ways, including, but not limited to, a straight line circuit, a splitter circuit, an arrayed waveguide grating wavelength multiplexer, and a cross connect-type circuit. Various types of waveguide circuits or devices can be utilized for the planar lightwave circuit in the embodiments of the present application.

Still referring to FIGS. 7A to 7B, in some embodiments, the second connector 43 includes the optical fibers 431 (which are connected to ends of the optical fibers 32 away from the light source device 10 as shown in FIG. 2 or may integrally extend from the optical fibers 32) and a mating component 432 structured to be detachably connected to the first connector 42. The optical fibers 431 have a plurality of fiber ends 433 terminated at the mating component 432 (as shown in FIG. 7A). In this embodiment, the mating component 432 functions as an optical multi-channel connector and includes a connecting surface 434 arranged facing the front end 420F of the base 420, and a plurality of recesses (not show) of the mating component 432 arranged to correspond to the pin-like positioning elements 423 (as shown in FIG. 7B). As shown in FIG. 7A, the second connector 43 is plugged into the first connector 42. As shown in FIG. 7B, the second connector 43 can be removed from the base 420 of the first connector 42.

In this arrangement, as shown in FIG. 7A, the fiber ends 433 of the optical fibers 431 are positioned to directly face the cutout portion 422 at the front end 420F of the base 420 to enable signal transmission between the optical fibers 431 and the waveguide component 421 in a way of surface coupling. It should be noted that the signal transmission between the optical fibers 431 and the waveguide component 421 is not limited to the surface coupling type as described above, and may be various in forms of optical coupling.

In the embodiments of the present application, the light source device of the optical coupling structure serves as an external light source (ELS) for the optoelectronic device and replaces conventional light source elements that are separately formed into a single piece, thus achieving optical coupling with multiple optical paths at one time and preventing the problem of high manufacturing costs and poor assembly efficiency resulting from the fact that conventional multiple light source elements each need to go through complicated and time-consuming optical alignment and coupling processes with lens components between the light source elements and optical fibers.

One aspect of the present application provides an optical coupling structure, adapted for an optoelectronic device, and the optical coupling structure includes a light source device including a fixed board, a bar substrate positioned on the fixed board, and a light unit positioned on the bar substrate. The light unit includes a functional portion and a light-emitting portion that are divided into a plurality of light emitters, and the bar substrate is configured to cross a bottom of each of the light emitters. A waveguide device is disposed adjacent to a mating surface included in the fixed board and the light emitters of the light source and enabling light signal transmission from the light emitters. An optical fiber assembly connected to the waveguide device.

Another aspect of the present disclosure provides a light source device, adapted for use with an optoelectronic device, and the light source device includes a fixed board; a bar substrate positioned on the fixed board; and a light unit positioned on the bar substrate and including a functional portion, a light-emitting portion, and a plurality of electrodes electrically connecting the light unit with the bar substrate. The functional portion and the light-emitting portion are divided into a plurality of light emitters, and the electrodes are arranged on the light emitters, respectively.

While the application has been disclosed in conjunction with a description of certain embodiments, including those that are currently believed to be the preferred embodiments, the detailed description is intended to be illustrative and should not be understood to limit the scope of the present application. As would be understood by one of ordinary skill in the art, embodiments other than those described in detail herein are encompassed by the present application. Modifications and variations of the described embodiments may be made without departing from the scope of the application.

What is claimed is:

1. An optical coupling structure, adapted for an optoelectronic device, the optical coupling structure comprising:
a light source device comprising a fixed board, a bar substrate positioned on the fixed board, and a light unit positioned on the bar substrate, wherein the light unit comprises a functional portion and a light-emitting portion that are divided into a plurality of light emitters, and the bar substrate is configured to cross a bottom of each of the light emitters;
a waveguide device disposed adjacent to a mating surface included in the fixed board and the light emitters of the light source and enabling light signal transmission from the light emitters; and
an optical fiber assembly connected to the waveguide device.

2. The optical coupling structure of claim 1, wherein the light emitters are spaced apart from each other and arranged in alignment with each other in an array.

3. The optical coupling structure of claim 1, wherein the bar substrate comprises an electrical circuit coupling with each of the light emitters and configured to provide a driving voltage to the light emitters.

4. The optical coupling structure of claim 1, wherein the light emitters are laser emitters and each of the light emitters is concurrently optically coupled with the waveguide device through a one-time active alignment process.

5. The optical coupling structure of claim 2, wherein the waveguide device comprises a plurality of optical waveguide paths spaced apart from each other at a same pitch as a pitch between adjacent ones of the light emitters.

6. The optical coupling structure of claim 5, wherein the bar substrate is positioned close to the mating surface of the fixed board, and the light emitters emit light beams in a straightforward direction toward the waveguide paths, respectively.

7. The optical coupling structure of claim 5, wherein the waveguide device comprises a guide surface located at a front end of the waveguide device, the waveguide paths extend to the guide surface, and the guide surface is configured to face and close to the mating surface of the fixed board device such that the light emitters are in alignment with the waveguide paths with a hollow space kept between the light emitters and the waveguide paths, respectively.

8. The optical coupling structure of claim 1, wherein the optical fiber assembly comprises a support seat and a plurality of optical fibers, part of the optical fibers is positioned at the support seat, and one end of each of the optical fibers is terminated at an edge of the support seat close to the waveguide device.

9. A light source device, adapted for use with an optoelectronic device, and comprising:
a fixed board;
a bar substrate positioned on the fixed board; and
a light unit positioned on the bar substrate and comprising a functional portion, a light-emitting portion, and a plurality of electrodes electrically connect the light unit to the bar substrate, wherein the functional portion and the light-emitting portion are divided into a plurality of light emitters, and the electrodes are arranged on the light emitters, respectively.

10. The light source device of claim 10, wherein the functional portion comprises an N-type semiconductor structure and a P-type semiconductor structure, and the light-emitting portion is disposed between the N-type semiconductor structure and the P-type semiconductor structure.

11. The light source device of claim 10, wherein the bar substrate comprises an electrical circuit coupling with each of the light emitters and configured to provide a control signal to the light emitters.

12. The light source device of claim 10, wherein a waveguide device and an optical fiber assembly are provided to optically coupled with the light source device, and the light emitters are spaced apart from each other and arranged in alignment with each other in an array.

13. The light source device of claim 13, wherein the light emitters are laser emitters and each of the light emitters is concurrently optically coupled with the waveguide device through a one-time active alignment process.

14. The light source device of claim 13, wherein the waveguide device comprises a plurality of optical waveguide paths spaced apart from each other at a same pitch as a pitch between adjacent ones of the light emitters.

15. The light source device of claim 15, wherein the waveguide device comprises a guide surface located at a front end of the waveguide device, the waveguide paths extend to the guide surface, and the guide surface is configured to face and close to a mating surface included in the light source device such that the light emitters are in alignment with the waveguide paths with a hollow space kept between the light emitters and the waveguide paths, respectively.

16. The light source device of claim 11, wherein a casing board is provided to support the optoelectronic device, and the optical coupling structure is mounted to the casing board, and the casing board, the optoelectronic device, and the optical coupling structure collectively form an optoelectronic system.

17. An optoelectronic system, comprising:
an optical coupling structure comprising:
a light source device comprising: a fixed board; a bar substrate positioned on the fixed board; and a light unit positioned on the bar substrate and comprising a functional portion and a light-emitting portion, wherein the functional portion and the light-emitting portion are divided into a plurality of light emitters; and
a waveguide device disposed adjacent to the fixed board and the light emitters of the light source device and enabling light signal transmission from the light emitters; and
an optical fiber assembly comprising a plurality of optical fibers and connected to the waveguide device; and
an optoelectronic device comprising a main circuit board and a plurality of detachable optical transceiver modules arranged on peripheral portions of the main circuit board, wherein each of the detachable optical transceiver module comprises:
a first connector disposed on the main circuit board and comprising:
a base; and
a waveguide component disposed in the base; and
a second connector disposed at one end of each optical fiber, wherein the second connector is detachably connected to the first connector.

18. The optoelectronic system of claim 17, wherein the light emitters are laser emitters and each of the light emitters is concurrently optically coupled with the waveguide device through a one-time active alignment process.

19. The optoelectronic system of claim 17, further comprising:
a casing board provided to support the optoelectronic device and the optical coupling structure.

20. The optoelectronic system of claim 17, wherein the optical fiber assembly comprises a support seat, part of the optical fibers is positioned at the support seat, and another end of each of the optical fibers is terminated at an edge of the support seat close to the waveguide device.
